(19) United States
(12) Patent Application Publication
(10) Pub. No.: US 2007/0207392 A1
(43) Pub. Date: Sep. 6, 2007

(54) Manufacturing method of photo mask and manufacturing method of semiconductor device

(76) Inventor: Yuji Kobayashi, Yokohama-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/638,427

(22) Filed: Dec. 14, 2006

(30) Foreign Application Priority Data
Dec. 16, 2005 (JP) 2005-363576

(51) Int. Cl. G03F 1/00; G03C 5/00

(52) U.S. Cl. 430/5; 430/394

(57) ABSTRACT

A manufacturing method of a photo mask includes: forming a metal film on a mask substrate; forming a positive resist film on the metal film; forming a negative resist film on the metal film; patterning the positive resist film with a first pattern to form a first resist pattern, the first pattern being to be transferred onto a resist film on a substrate and then to be resolved, a semiconductor device is to be formed on the substrate; patterning the negative resist film with a second pattern to form a second resist pattern, the second pattern being intended to improve a resolution performance of the first pattern and including an auxiliary pattern which is not resolved on the substrate, the semiconductor device is to be formed on the substrate; and processing the metal film by use of the first resist pattern and the second resist pattern.

### CROSS REFERENCE TO RELATED APPLICATION

This application claims benefit of priority under 35USC §119 to Japanese patent application No. 2005-363576, filed on Dec. 16, 2005, the contents of which are incorporated by reference herein.

### BACKGROUND OF THE INVENTION

1. Field of the Invention

The present invention relates to a manufacturing method of a photo mask and a manufacturing -method of a semiconductor device.

2. Related Background Art

It is known that when modified illumination such as oblique incidence is applied to a photo mask, a focal depth increases as compared with vertical illumination. Therefore, in a field of photolithography, a technology is used in which a sub-resolution assist feature (SRAF) is arranged adjacent to an actual pattern to be transferred and resolved onto a wafer, and periodicity of the actual pattern is adjusted to thereby improve a resolution performance. The above SRAF is an auxiliary pattern having a width below a limit resolution during wafer transfer, and is not transferred and not resolved onto a semiconductor substrate.

However, when the SRAF is used, a dimension of the actual pattern to be transferred onto the semiconductor substrate fluctuates depending on a dimensional precision of the SRAF in addition to a dimensional precision of the actual pattern on the mask.

In the existing circumstances, when a pattern is formed on the photo mask, both the SRAF and the actual pattern are simultaneously formed in one lithography process. Therefore, both the patterns have a similar dimensional tendency in a mask surface, and a problem occurs in uniformity of a dimension in a shot at a time when the pattern is transferred onto the semiconductor substrate.

### SUMMARY OF THE INVENTION

According to a first aspect of the present invention, there is provided a manufacturing method of a photo mask comprising:

forming a metal film on a mask substrate;

forming a positive resist film on the metal film;

forming a negative resist film on the metal film;

patterning the positive resist film with a first pattern to form a first resist pattern, the first pattern being to be transferred onto a resist film on a substrate and then to be resolved, a semiconductor device is to be formed on the substrate;

patterning the negative resist film with a second pattern to form a second resist pattern, the second pattern being intended to improve a resolution performance of the first pattern and including an auxiliary pattern which is not resolved on the substrate, the semiconductor device is to be formed on the substrate; and

processing the metal film by use of the first resist pattern and the second resist pattern.

According to a second aspect of the present invention, there is provided a manufacturing method of a photo mask comprising:

forming a metal film on a mask substrate;

forming a positive resist film on the metal film;

forming a negative resist film on the metal film;

patterning the negative resist film with a first pattern to form a first resist pattern, the first pattern being to be transferred onto a resist film on a substrate and then to be resolved, a semiconductor device is to be formed on the substrate;

patterning the positive resist film with a second pattern to form a second resist pattern, the second pattern being intended to improve a resolution performance of the first pattern and including an auxiliary pattern which is not resolved on the substrate, the semiconductor device is to be formed on the substrate; and

processing the metal film by use of the first resist pattern and the second resist pattern.

According to a third aspect of the present invention, there is provided a manufacturing method of a semiconductor device comprising:

forming a first pattern on a substrate, the first pattern being to be transferred onto a resist film on the substrate by use of a photo mask manufactured by a manufacturing method of the photo mask and which is then to be resolved, the manufacturing method of the photo mask comprising:

forming a metal film on a mask substrate;

forming a positive resist film on the metal film;

forming a negative resist film on the metal film;

patterning the positive resist film with the first pattern to form a first resist pattern;

patterning the negative resist film with a second pattern to form a second resist pattern, the second pattern being intended to improve a resolution performance of the first pattern and including an auxiliary pattern which is not resolved on the substrate on which the semiconductor device is to be formed; and

processing the metal film by use of the first resist pattern and the second resist pattern.

According to a fourth aspect of the present invention, there is provided a manufacturing method of a semiconductor device comprising:

forming a first pattern on a substrate, the first pattern being to be transferred onto a resist film on the substrate by use of a photo mask manufactured by a manufacturing method of the photo mask and which is then to be resolved, the manufacturing method of the photo mask comprising:

forming a metal film on a mask substrate;

forming a positive resist film on the metal film;

forming a negative resist film on the metal film;

patterning the negative resist film with the first pattern to form a first resist pattern;

patterning the positive resist film with a second pattern to form a second resist pattern, the second pattern being intended to improve a resolution performance of the first pattern and including an auxiliary pattern which is not resolved on the substrate on which the semiconductor device is to be formed; and

processing the metal film by use of the first resist pattern and the second resist pattern.

### BRIEF DESCRIPTION OF THE DRAWINGS

In the accompanying drawings:

FIGS. 1A to 1F are schematic sectional views showing a first embodiment of a manufacturing method of a photo mask according to the present invention;

FIGS. 2A to 2F are schematic sectional views showing a second embodiment of a manufacturing method of a photo mask according to the present invention;

FIGS. 3A to 3F are schematic sectional views showing a third embodiment of a manufacturing method of a photo mask according to the present invention;

FIGS. 4A to 4F are schematic sectional views showing a fourth embodiment of a manufacturing method of a photo mask according to the present invention;

FIGS. 5A to 5F are schematic sectional views showing a fifth embodiment of a manufacturing method of a photo mask according to the present invention;

FIGS. 6A to 6F are schematic sectional views showing a sixth embodiment of a manufacturing method of a photo mask according to the present invention;

FIGS. 7A to 7F are schematic sectional views showing a seventh embodiment of a manufacturing method of a photo mask according to the present invention; and

FIGS. 8A to 8F are schematic sectional views showing an eighth embodiment of a manufacturing method of a photo mask according to the present invention.

### DETAILED DESCRIPTION OF THE INVENTION

Embodiments of the present invention will hereinafter be described with reference to the drawings.

(A) Manufacturing Method of Photo Mask

Each of photo mask manufacturing methods described in the following embodiments is characterized in that an actual pattern and an SRAF are individually prepared using mutually different resists which are positive and negative. The actual pattern and the SRAF are transferred in processes which have an inverse correlation in this manner to prepare a metal film. Therefore, dimensional tendencies in a mask surface can be reversed between these patterns. In consequence, it is possible to manufacture a photo mask in which a dimensional uniformity in a shot of the actual pattern can be improved.

In the following embodiments, the actual pattern corresponds to, for example, a first pattern, and the SRAF corresponds to, for example, a second pattern.

In the following, remaining patterns (first to fourth) and removed patterns (fifth to eighth) are separately used to describe the embodiments of the photo mask manufacturing method according to the present invention more specifically.

### (1) First Embodiment

In the present embodiment, 1) a remaining pattern is used, a) an SRAF is formed using a negative resist and an actual pattern is formed using a positive resist, and 1) the actual pattern is prepared prior to the SRAF.

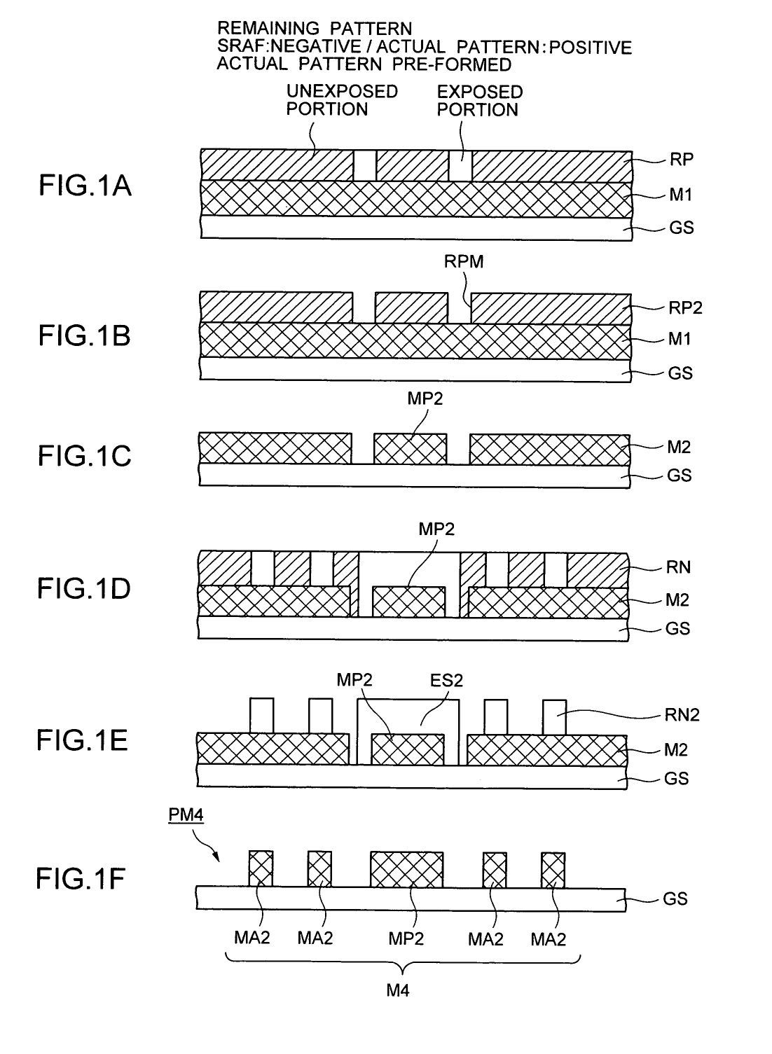

FIGS. 1A to 1F are schematic sectional views showing a mask manufacturing method of the present embodiment. First, as shown in FIG. 1A, a chromium film M1 formed on a glass substrate GS is coated with a positive resist film RP, the actual pattern is drawn thereon, and the positive resist film RP is exposed. In FIG. 1A, in the resist film, each white portion indicates an exposed portion, and each hatched portion indicates an unexposed portion. This respect similarly applies to FIGS. 1B to 8F described hereinafter.

Next, as shown in FIG. 1B, the positive resist film RP is developed to acquire a positive resist RP2 having portions RPM in a shape corresponding to that of the actual pattern, and etching is then carried out by use of this resist as a mask to selectively remove the chromium film M1. In the present embodiment, the positive resist RP2 corresponds to, for example, a first resist pattern.

Furthermore, as shown in FIG. 1C, the positive resist RP2 is peeled to thereby prepare a chromium film M2 including a portion MP2 in a shape corresponding to that of the actual pattern.

Next, as shown in FIG. 1D, the whole surface is coated with a negative resist film RN, and the SRAF is then exposed. Subsequently, as shown in FIG. 1E, the negative resist film RN is developed to prepare a negative resist RN2 from which a portion in a shape corresponding to that of the SRAF has been removed. At this time, the negative resist RN2 is prepared so as to simultaneously form an etching stopper ES2 which protects, from etching of the next process, the portion MP2 in a shape corresponding to that of the actual pattern in the chromium film M2 already prepared. In the present embodiment, the negative resist RN2 corresponds to, for example, a second resist pattern.

Furthermore, etching is carried out by use of the negative resist RN2 as a mask to selectively remove the chromium film M2. In consequence, as shown in FIG. 1F, a photo mask PM4 is prepared which comprises a chromium film M4 including the portion MP2 having a shape in a shape corresponding to that of the actual pattern and portions MA2 having shapes corresponding to the SRAF.

### (2) Second Embodiment

In the present embodiment, 1) a remaining pattern is used, a) an SRAF is formed using a negative resist and an actual pattern is formed using a positive resist, and 1) the SRAF is prepared prior to the actual pattern.

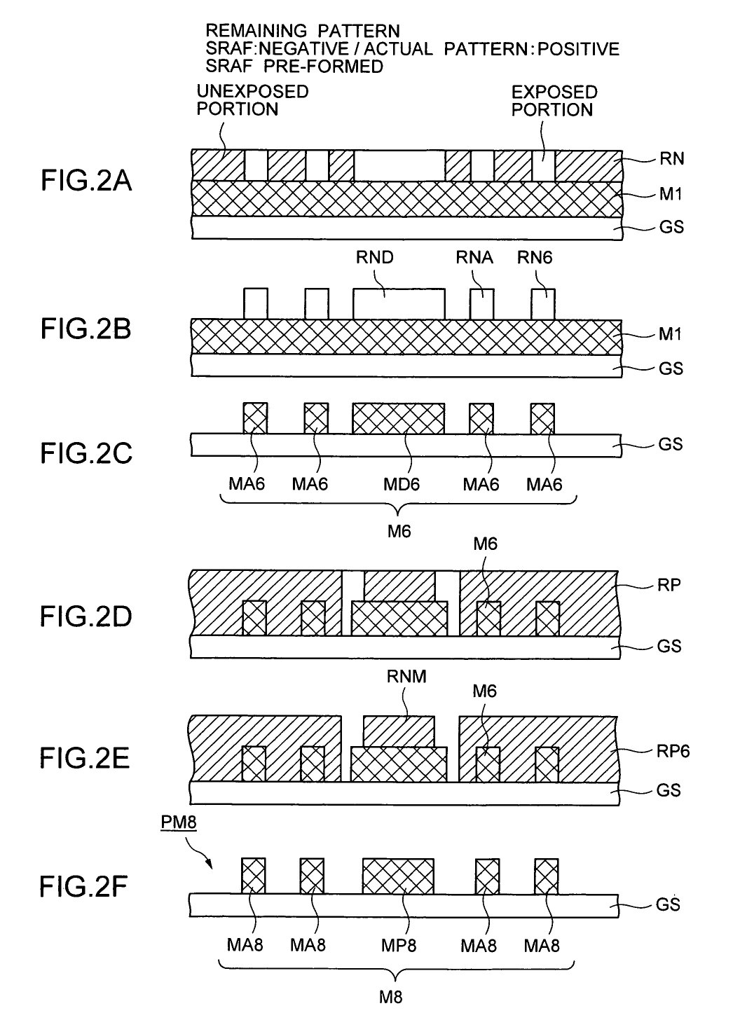

FIGS. 2A to 2F are schematic sectional views showing a mask manufacturing method of the present embodiment. First, as shown in FIG. 2A, a chromium film M1 formed on a glass substrate GS is coated with a negative resist film RN, the SRAF is drawn thereon, and the negative resist film RN is exposed.

Next, as shown in FIG. 2B, the negative resist film RN is developed to acquire a negative resist RN6 having a portion RNA in a shape corresponding to that of the SRAF and an actual pattern portion RND to be processed including an alignment margin during preparation of the actual pattern. Then, etching is carried out by use of this resist as a mask to selectively remove the chromium film M1. In the present embodiment, the negative resist RN6 corresponds to, for example, a second resist pattern.

Subsequently, the negative resist RN6 is peeled to thereby prepare a chromium film M6 including portions MA6 corresponding to the shape of the SRAF and an actual pattern portion MD6 to be processed, as shown in FIG. 2C.

Next, as shown in FIG. 2D, the whole surface is coated with a positive resist film RP, and the actual pattern is then exposed. Subsequently, as shown in FIG. 2E, the positive resist film RP is developed to prepare a positive resist RP6 in which a portion RNM in a shape corresponding to that of the actual pattern is left. In the present embodiment, the positive resist RP6 corresponds to, for example, a first resist pattern.

Furthermore, etching is carried out by use of the portion RNM in a shape corresponding to that of the actual pattern in the positive resist RP6 as a mask to selectively remove the chromium film M6. In consequence, as shown in FIG. 2F, a photo mask PM8 is prepared which comprises a chromium film M8 including a portion MP8 having a shape corresponding to that of the actual pattern and portions MA8 having shapes corresponding to that of the SRAF.

### (3) Third Embodiment

In the present embodiment, 1) a remaining pattern is used, a) an SRAF is formed using a positive resist and an actual pattern is formed using a negative resist, and 1) the actual pattern is prepared prior to the SRAF.

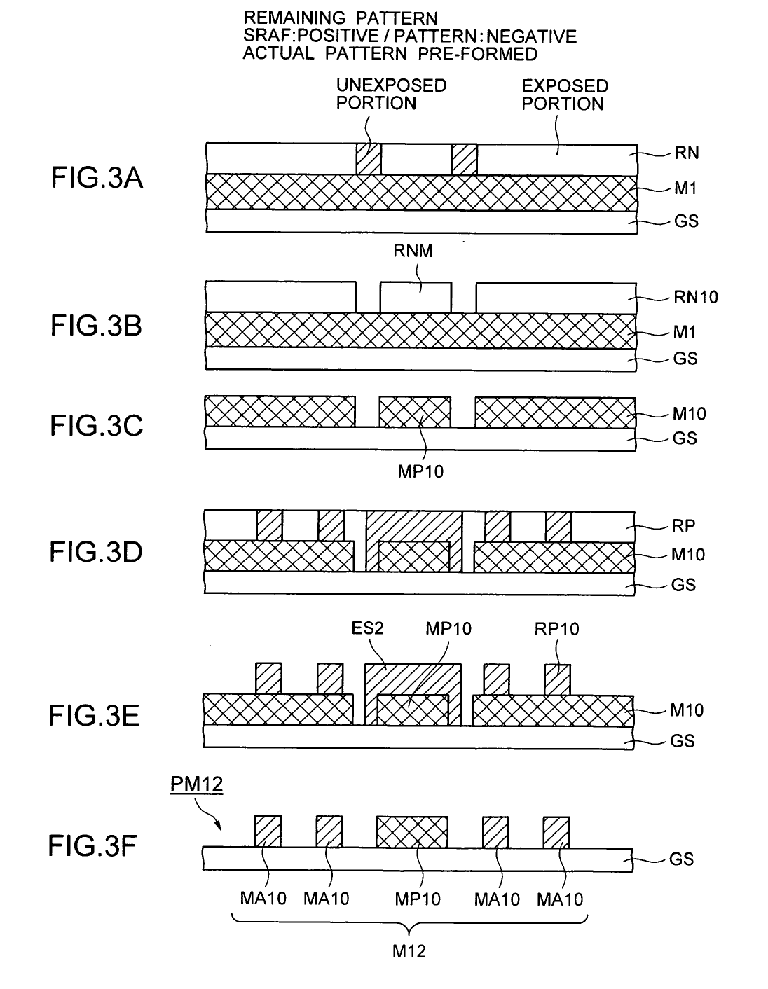

FIGS. 3A to 3F are schematic sectional views showing a mask manufacturing method of the present embodiment. First, as shown in FIG. 3A, a chromium film M1 on a glass substrate GS is coated with a negative resist film RN, and the actual pattern is then exposed.

Next, as shown in FIG. 3B, the negative resist film RN is developed to acquire a negative resist RN10 having a portion RNM in a shape corresponding to that of the actual pattern, and etching is then carried out by use of this resist as a mask to selectively remove the chromium film M1. In the present embodiment, the negative resist RN10 corresponds to, for example, a first resist pattern.

Furthermore, as shown in FIG. 3C, the negative resist RN10 is peeled to thereby prepare a chromium film M10 including a portion MP10 in a shape corresponding to that of the actual pattern.

Next, as shown in FIG. 3D, the whole surface is coated with a positive resist film RP, and the SRAF is then exposed. Subsequently, as shown in FIG. 3E, the positive resist film RP is developed to prepare a positive resist RP10 having a portion corresponding to a shape of the SRAF. At this time, the positive resist RP10 is processed so as to simultaneously form an etching stopper ES2 which protects, from etching of the next process, the portion MP10 in a shape corresponding to that of the actual pattern in the chromium film M10 already prepared. In the present embodiment, the positive resist RP10 corresponds to, for example, a second resist pattern.

Furthermore, etching is carried out by use of the positive resist RP10 as a mask to selectively remove the chromium film M10. In consequence, as shown in FIG. 3F, a photo mask PM12 is prepared which comprises a chromium film M12 including the portion MP10 having a shape corresponding to the actual pattern and portions MA10 having shapes corresponding to the SRAF.

### (4) Fourth Embodiment

In the present embodiment, 1) a remaining pattern is used, a) an SRAF is formed using a positive resist and an actual pattern is formed using a negative resist, and 1) the SRAF is prepared prior to the actual pattern.

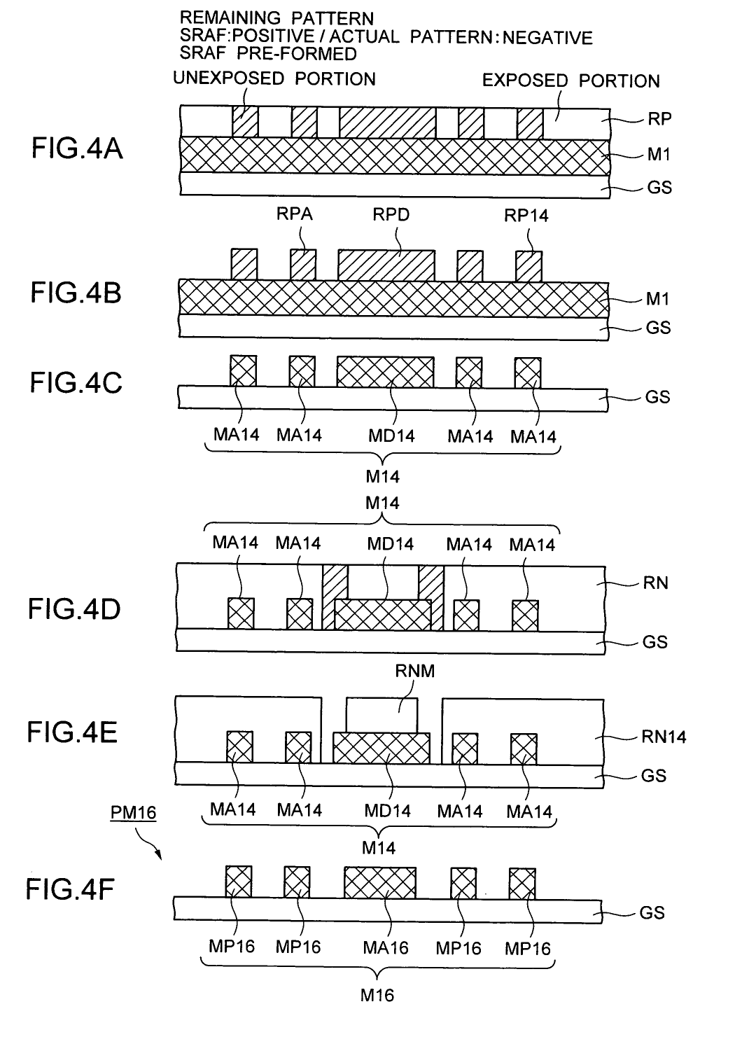

FIGS. 4A to 4F are schematic sectional views showing a mask manufacturing method of the present embodiment. First, as shown in FIG. 4A, a chromium film M1 formed on a glass substrate GS is coated with a positive resist film RP, and the SRAF is then exposed.

Next, as shown in FIG. 4B, the positive resist film RP is developed to acquire a positive resist RP14 having a portion RPA in a shape corresponding to that of the SRAF and an actual pattern portion RPD to be processed including an alignment margin during preparation of the actual pattern. Then, etching is carried out by use of this resist as a mask to selectively remove chromium film M1. In the present embodiment, the positive resist RP14 corresponds to, for example, a second resist pattern.

Subsequently, the positive resist RP14 is peeled to thereby prepare a chromium film M14 including portions MA14 corresponding to the shape of the SRAF and an actual pattern portion MD14 to be processed, as shown in FIG. 4C.

Next, as shown in FIG. 4D, the whole surface is coated with a negative resist film RN, and the actual pattern is then exposed. Subsequently, as shown in FIG. 4E, the negative resist film RN is developed to prepare a negative resist RN14 in which a portion RNM corresponding to a shape of the actual pattern is left. In the present embodiment, the negative resist RN14 corresponds to, for example, a second resist pattern.

Furthermore, etching is carried out by use of the negative resist RN14 as a mask to selectively remove the chromium film M14. In consequence, as shown in FIG. 4F, a photo mask PM16 is prepared which comprises a chromium film M16 including portions MP16 having shapes corresponding to the actual pattern and a portion MA16 having a shape corresponding to the SRAF.

### (5) Fifth Embodiment

In the present embodiment, 2) a removed pattern is used, a) an SRAF is formed using a positive resist and an actual pattern is formed using a negative resist, and 1) the actual pattern is prepared prior to the SRAF.

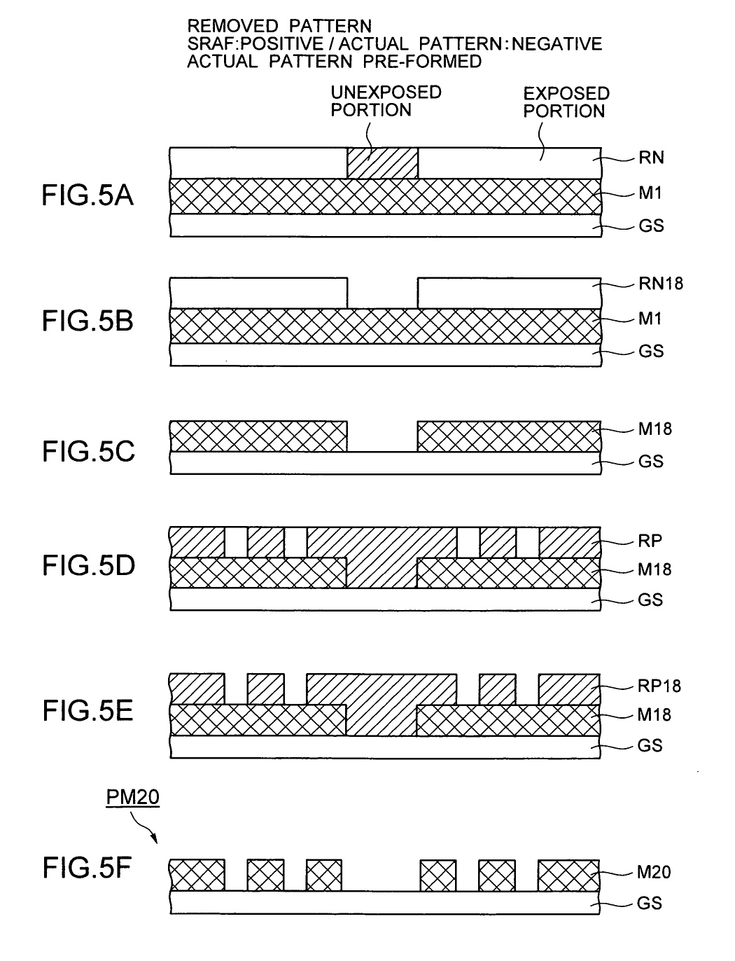

FIGS. 5A to 5F are schematic sectional views showing a mask manufacturing method of the present embodiment. First, as shown in FIG. 5A, a chromium film M1 on a glass substrate GS is coated with a negative resist film RN, and the actual pattern is drawn thereon. In the resist film RN, a portion corresponding to the actual pattern is not exposed and portions other than the actual pattern are exposed.

Next, as shown in FIG. 5B, the negative resist film RN is developed to acquire a negative resist RN18 from which the portion in a shape corresponding to that of the actual pattern has been removed, and etching is then carried out by use of this resist as a mask to selectively remove the chromium film M1. In the present embodiment, the negative resist RN18 corresponds to, for example, a first resist pattern.

Furthermore, as shown in FIG. 5C, the negative resist RN18 is peeled to thereby prepare a chromium film M18 from which the portion in a shape corresponding to that of the actual pattern has been removed.

Next, as shown in FIG. 5D, the whole surface is coated with a positive resist film RP, and the SRAF is drawn thereon. In the positive resist film RP, a portion corresponding to the SRAF is exposed. Subsequently, as shown in FIG. 5E, the positive resist film RP is developed to prepare a positive resist RP18 from which an exposed portion in a shape corresponding to that the SRAF has been removed. In the present embodiment, the positive resist RP18 corresponds to, for example, a second resist pattern.

Furthermore, etching is carried out by use of the positive resist RP18 as a mask to further selectively remove the chromium film M18. In consequence, as shown in FIG. 5F, a photo mask PM20 is prepared which comprises a chromium film M20 from which the portion in a shape corresponding to that of the actual pattern and the portion in a shape corresponding to that of the SRAF have been removed.

### (6) Sixth Embodiment

In the present embodiment, 2) a removed pattern is used, a) an SRAF is formed using a positive resist and an actual pattern is formed using a negative resist, and 2) the SRAF is prepared prior to the actual pattern.

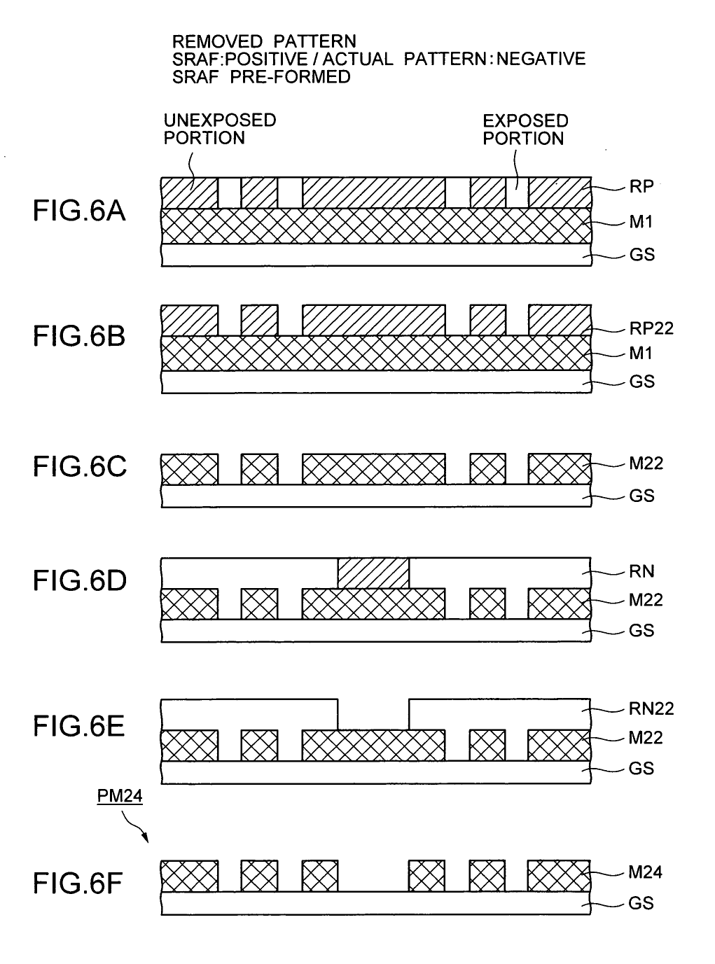

FIGS. 6A to 6F are schematic sectional views showing a mask manufacturing method of the present embodiment. First, as shown in FIG. 6A, a chromium film M1 on a glass substrate GS is coated with a positive resist film RP, and the SRAF is drawn thereon. In the resist film RP, a portion corresponding to the SRAF is exposed.

Next, as shown in FIG. 6B, the positive resist film RP is developed to acquire a positive resist RP22 from which the portion in a shape corresponding to that of the SRAF has been removed, and etching is then carried out by use of this resist as a mask to selectively remove the chromium film M1. In the present embodiment, the positive resist RP22 corresponds to, for example, a second resist pattern.

Furthermore, the positive resist RP22 is peeled to thereby prepare a chromium film M22 from which a portion in a shape corresponding to that of the actual pattern has been removed, as shown in FIG. 6C.

Next, as shown in FIG. 6D, the whole surface is coated with a negative resist film RN, and the actual pattern is drawn thereon. In the negative resist film RN, the portion corresponding to the actual pattern is not exposed, and portions other than the actual pattern are exposed. Subsequently, as shown in FIG. 6E, the negative resist film RN is developed to prepare a negative resist RN22 from which an exposed portion in a shape corresponding to that of the actual pattern has been removed. In the present embodiment, the negative resist RN22 corresponds to, for example, a first resist pattern.

Furthermore, etching is carried out by use of the negative resist RN22 as a mask to further selectively remove the chromium film M22. In consequence, as shown in FIG. 6F, a photo mask PM24 is prepared which comprises a chromium film M24 from which the portion in a shape corresponding to that of the actual pattern and the portion in a shape corresponding to that of the SRAF have been removed.

### (7) Seventh Embodiment

In the present embodiment, 2) a removed pattern is used, a) an SRAF is formed using a negative resist and an actual pattern is formed using a positive resist, and 1) the actual pattern is prepared prior to the SRAF.

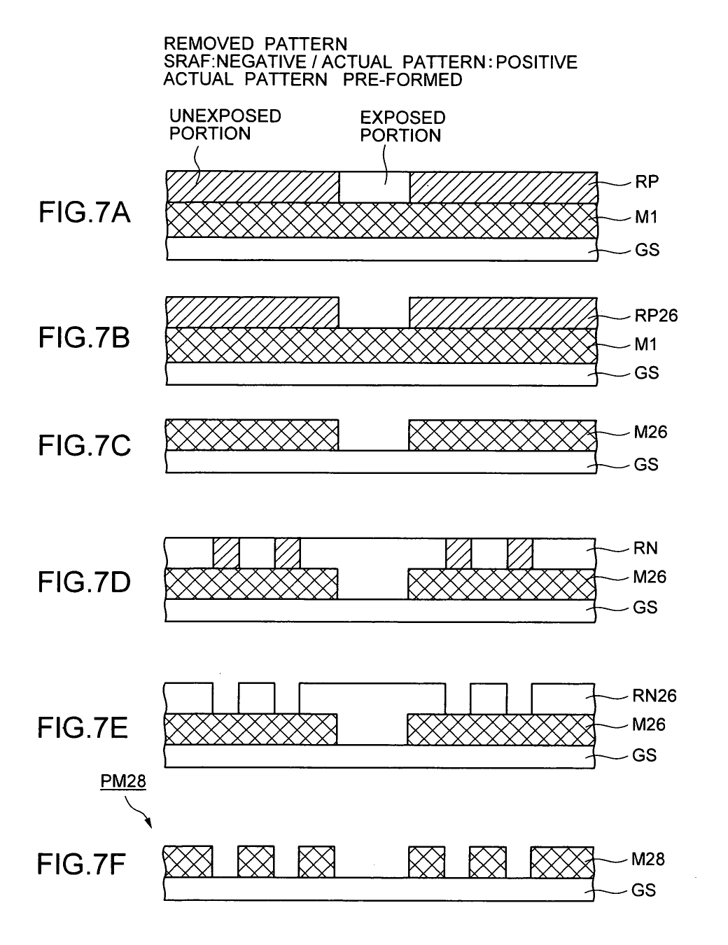

FIGS. 7A to 7F are schematic sectional views showing a mask manufacturing method of the present embodiment. First, as shown in FIG. 7A, a chromium film M1 on a glass substrate GS is coated with a positive resist film RP, and the actual pattern is drawn. In the resist film RP, a portion corresponding to the actual pattern is exposed.

Next, as shown in FIG. 7B, the positive resist film RP is developed to acquire a positive resist RP26 from which the portion in a shape corresponding to that of the actual pattern has been removed, and etching is then carried out by use of this resist as a mask to selectively remove the chromium film M1. In the present embodiment, the positive resist RP26 corresponds to, for example, a first resist pattern.

Furthermore, the positive resist RP26 is peeled to thereby prepare a chromium film M26 from which the portion in a shape corresponding to that of the actual pattern has been removed, as shown in FIG. 7C.

Next, as shown in FIG. 7D, the whole surface is coated with a negative resist film RN, and the SRAF is drawn thereon. In the negative resist film RN, a portion corresponding to the SRAF is not exposed, and portions other than the SRAF portion are exposed. Subsequently, as shown in FIG. 7E, the negative resist film RN is developed to prepare a negative resist RN26 from which an unexposed portion in a shape corresponding to that of the SRAF has been removed. In the present embodiment, the negative resist RN26 corresponds to, for example, a second resist pattern.

Furthermore, etching is carried out by use of the negative resist RN26 as a mask to further selectively remove the chromium film M26. In consequence, as shown in FIG. 7F, a photo mask PM28 is prepared which comprises a chromium film M28 from which the portion in a shape corresponding to that of the actual pattern and the portion in a shape corresponding to that of the SRAF have been removed.

### (8) Eighth Embodiment

In the present embodiment, 2) a removed pattern is used, b) an SRAF is formed using a negative resist and an actual pattern is formed using a positive resist, and 2) the SRAF is prepared prior to the actual pattern.

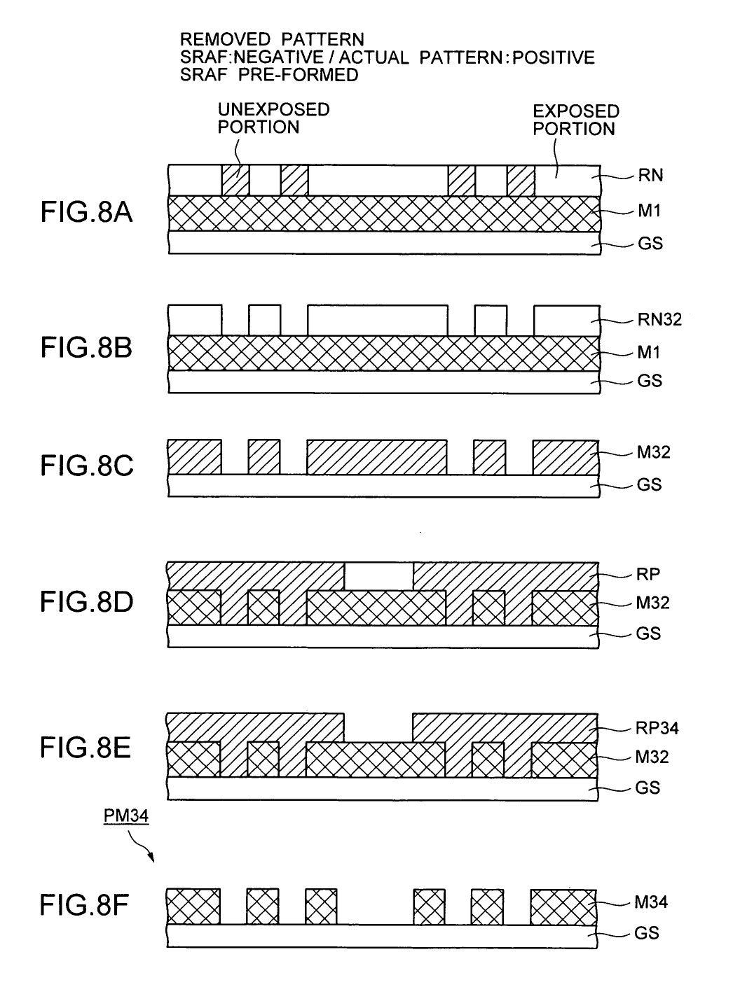

FIGS. 8A to 8F are schematic sectional views showing a mask manufacturing method of the present embodiment. First, as shown in FIG. 8A, a chromium film M1 on a glass substrate GS is coated with a negative resist film RN, and the SRAF is drawn thereon. In the resist film RN, a portion corresponding to the SRAF is not exposed, and portions other than the SRAF are exposed.

Next, as shown in FIG. 8B, the negative resist film RN is developed to acquire a negative resist RN32 from which the portion in a shape corresponding to that of the SRAF has been removed, and etching is then carried out by use of this resist as a mask to selectively remove the chromium film M1. In the present embodiment, the negative resist RN32 corresponds to, for example, a second resist pattern.

Furthermore, the negative resist RN32 is peeled to thereby prepare a chromium film M32 from which the portion in a shape corresponding to that of the SRAF has been removed, as shown in FIG. 8C.

Next, as shown in FIG. 8D, the whole surface is coated with a positive resist film RP, and the actual pattern is drawn thereon. In the positive resist film RP, a portion corresponding to the actual pattern is exposed. Subsequently, as shown in FIG. 8E, the positive resist film RP is developed to prepare a positive resist RP34 from which an exposed portion in a shape corresponding to that of the actual pattern has been removed. In the present embodiment, the negative resist RP34 corresponds to, for example, a first resist pattern.

Furthermore, etching is carried out by use of the positive resist RP34 as a mask to further selectively remove the chromium film M32. In consequence, as shown in FIG. 8F, a photo mask PM34 is prepared which comprises a chromium film M34 from which the portion in a shape corresponding to that of the actual pattern and the portion in a shape corresponding to that of the SRAF have been removed.

(B) Manufacturing Method of Semiconductor Device

When a semiconductor device is manufactured by use of any of photo masks manufactured according to the above embodiments, a dimensional uniformity of an actual pattern in each shot improves. Therefore, it is possible to manufacture the highly precise semiconductor device in a high yield.

The embodiments of the present invention have been described above, but, needless to say, the present invention is not limited to the above embodiments, and can variously be modified and performed in a technical scope of the present invention.

What is claimed is:

1. A manufacturing method of a photo mask comprising:
forming a metal film on a mask substrate;
forming a positive resist film on the metal film;
forming a negative resist film on the metal film;
patterning the positive resist film with a first pattern to form a first resist pattern, the first pattern being to be transferred onto a resist film on a substrate and then to be resolved, a semiconductor device is to be formed on the substrate;
patterning the negative resist film with a second pattern to form a second resist pattern, the second pattern being intended to improve a resolution performance of the first pattern and including an auxiliary pattern which is not resolved on the substrate, the semiconductor device is to be formed on the substrate; and
processing the metal film by use of the first resist pattern and the second resist pattern.

2. The manufacturing method of the photo mask according to claim 1,
wherein the positive resist film is formed prior to the negative resist film.

3. The manufacturing method of the photo mask according to claim 2,
wherein the metal film is processed so as to have a portion in a shape corresponding to the first pattern and a portion in a shape corresponding to the auxiliary pattern.

4. The manufacturing method of the photo mask according to claim 2,
wherein the metal film is processed so that a portion in a shape corresponding to the first pattern and a portion in a shape corresponding to the auxiliary pattern are removed.

5. The manufacturing method of the photo mask according to claim 1,
wherein the negative resist film is formed prior to the positive resist film.

6. The manufacturing method of the photo mask according to claim 5,
wherein the metal film is processed so as to have a portion in a shape corresponding to the first pattern and a portion in a shape corresponding to the auxiliary pattern.

7. The manufacturing method of the photo mask according to claim 5,
wherein the metal film is processed so that a portion in a shape corresponding to the first pattern and a portion in a shape corresponding to the auxiliary pattern are removed.

8. A manufacturing method of a photo mask comprising:
forming a metal film on a mask substrate;
forming a positive resist film on the metal film;
forming a negative resist film on the metal film;
patterning the negative resist film with a first pattern to form a first resist pattern, the first pattern being to be transferred onto a resist film on a substrate and then to be resolved, a semiconductor device is to be formed on the substrate;
patterning the positive resist film with a second pattern to form a second resist pattern, the second pattern being intended to improve a resolution performance of the first pattern and including an auxiliary pattern which is not resolved on the substrate, the semiconductor device is to be formed on the substrate; and
processing the metal film by use of the first resist pattern and the second resist pattern.

9. The manufacturing method of the photo mask according to claim 8,
wherein the positive resist film is formed prior to the negative resist film.

10. The manufacturing method of the photo mask according to claim 9,
wherein the metal film is processed so as to have a portion in a shape corresponding to the first pattern and a portion in a shape corresponding to the auxiliary pattern.

11. The manufacturing method of the photo mask according to claim 9,
wherein the metal film is processed so that a portion in a shape corresponding to the first pattern and a portion in a shape corresponding to the auxiliary pattern are removed.

12. The manufacturing method of the photo mask according to claim 8,
wherein the negative resist film is formed prior to the positive resist film.

13. The manufacturing method of the photo mask according to claim 12,
wherein the metal film is processed so as to have a portion in a shape corresponding to the first pattern and a portion in a shape corresponding to the auxiliary pattern.

14. The manufacturing method of the photo mask according to claim 12,
wherein the metal film is processed so that a portion in a shape corresponding to the first pattern and a portion in a shape corresponding to the auxiliary pattern are removed.

15. A manufacturing method of a semiconductor device comprising:
forming a first pattern on a substrate, the first pattern being to be transferred onto a resist film on the substrate by use of a photo mask manufactured by a manufacturing method of the photo mask and which is then to be resolved, the manufacturing method of the photo mask comprising:
forming a metal film on a mask substrate;
forming a positive resist film on the metal film;
forming a negative resist film on the metal film;
patterning the positive resist film with the first pattern to form a first resist pattern;
patterning the negative resist film with a second pattern to form a second resist pattern, the second pattern being intended to improve a resolution performance of the first pattern and including an auxiliary pattern which is not resolved on the substrate on which the semiconductor device is to be formed; and
processing the metal film by use of the first resist pattern and the second resist pattern.

16. The manufacturing method of the semiconductor device according to claim 15,
wherein the positive resist film is formed prior to the negative resist film.

17. The manufacturing method of the semiconductor device according to claim 15,
wherein the negative resist film is formed prior to the positive resist film.

18. A manufacturing method of a semiconductor device comprising:
forming a first pattern on a substrate, the first pattern being to be transferred onto a resist film on the substrate by use of a photo mask manufactured by a manufacturing method of the photo mask and which is then to be resolved, the manufacturing method of the photo mask comprising:
forming a metal film on a mask substrate;
forming a positive resist film on the metal film;
forming a negative resist film on the metal film;
patterning the negative resist film with the first pattern to form a first resist pattern;
patterning the positive resist film with a second pattern to form a second resist pattern, the second pattern being intended to improve a resolution performance of the first pattern and including an auxiliary pattern which is not resolved on the substrate on which the semiconductor device is to be formed; and
processing the metal film by use of the first resist pattern and the second resist pattern.

19. The manufacturing method of the semiconductor device according to claim 18,
wherein the positive resist film is formed prior to the negative resist film.

20. The manufacturing method of the semiconductor device according to claim 18,
wherein the negative resist film is formed prior to the positive resist film.
